(19) United States
(12) Patent Application Publication
(10) Pub. No.: US 2026/0173786 A1
(43) Pub. Date: Jun. 18, 2026

(54) CHEMICAL MECHANICAL PLANARIZATION METHOD AND APPARATUS IN SEMICONDUCTOR MANUFACTURING PROCESS

(71) Applicant: KOREA ADVANCED NANO FAB CENTER, Suwon-si (KR)

(72) Inventors: Dong Hwan JUN, Yongin-si (KR); Shin Keun KIM, Yongin-si (KR); Chang Hwan KIM, Suwon-si (KR); Gwan Yeol PARK, Suwon-si (KR); Taek KIM, Seongnam-si (KR)

(73) Assignee: KOREA ADVANCED NANO FAB CENTER, Suwon-si (KR)

(21) Appl. No.: 18/989,288

(22) Filed: Dec. 20, 2024

(30) Foreign Application Priority Data
Oct. 14, 2024 (KR) 10-2024-0139202

(51) Int. Cl. H01L 21/321; H01L 21/304; H10N 60/01

(52) U.S. Cl. CPC H10P 52/403; H10N 60/0156; H10P 52/00

(57) ABSTRACT

Disclosed are a chemical mechanical planarization method in a semiconductor manufacturing process, wherein the chemical mechanical planarization method is performed to apply an electric field to the surface of a wafer using an electrophoretic phenomenon during a chemical mechanical planarization (CMP) process in order to control the distribution of charged particles in a slurry, and a chemical mechanical planarization apparatus in a semiconductor manufacturing process, wherein the chemical mechanical planarization apparatus includes CMP equipment configured to perform a CMP process of planarizing the surface of a wafer and an electric field application controller configured to apply an electric field to the surface of the wafer during the CMP process.

### CROSS-REFERENCE TO PRIOR APPLICATIONS

This Application claims priority to Korean Patent Application No. 10-2024-0139202 filed Dec. 14, 2024, which is all hereby incorporated by reference in their entirety.

### BACKGROUND OF THE INVENTION

### 1. Field of the invention

The present invention relates to a chemical mechanical planarization method and apparatus in a semiconductor manufacturing process, and more particularly to a chemical mechanical planarization method and apparatus in a semiconductor manufacturing process capable of controlling the planarization and etch rate of the surface of a wafer using an electrophoretic phenomenon.

### 2. Description of the Related Art

Semiconductor chips used in quantum technology require a very high level of accuracy and reliability. In particular, in fields such as quantum computing or quantum communication, the surface flatness of the semiconductor chips has a great influence on signal transmission speed and energy loss.

A chemical mechanical planarization (CMP) process is an essential step in semiconductor chip manufacturing, which removes and planarizes the non-uniform surface between layers in a multilayered semiconductor device.

In particular, unlike general semiconductor devices, quantum devices have fine patterns and structures, requiring a higher-level CMP process to minimize surface non-uniformity. In addition, if the surface of a metal interconnection layer used in quantum devices is not uniform, the flow of current becomes unstable during signal transmission.

Reducing dishing and erosion issues is key to the CMP process required for chips for quantum technology. Dishing is a phenomenon in which the metal interconnection layer is excessively polished, resulting in caving in, and erosion is a phenomenon in which a dielectric layer (dielectric material) rather than a target material is unintentionally etched, resulting in degradation of surface uniformity.

FIG. 1A is a schematic view showing the profile of a semiconductor device before a conventional CMP process, FIG. 1B is a schematic view showing a surface after an ideal CMP process, and FIG. 1C is a schematic view showing dishing and erosion phenomena caused by a CMP process.

The dishing and erosion phenomena may disrupt the fine structure of quantum devices and the accuracy of signal transmission. In addition, the CMP process in quantum technology requires more precise planarization than in general semiconductor devices, and control of the initial topography and management of chemical compositions of a slurry are critical.

Since highly precise planarization is required for semiconductor devices for quantum technology, dishing due to excessive polishing of the metal layer during the CMP process may be a major problem. Dishing may cause uneven thickness of a metal line, distorting a signal transmission path and degrading the performance of the quantum device.

In addition, erosion, which is excessive etching of the dielectric layer rather than the target material, destroys the uniformity of the surface and destabilizes the electrical properties of the quantum device. This may increase energy losses during signal transmission and reduce the accuracy of high-performance quantum computing systems.

In addition, if the initial topography is not uniform, uniformity of the surface may not be sufficiently secured even after the CMP process. In particular, the microscopic structure in quantum technology devices is sensitive to such non-uniformity.

In addition, oxidation or contamination issues may occur during wafer transfer during the CMP process, which may affect electrical properties, which are particularly important in quantum devices, and lead to poor process quality.

Therefore, in a semiconductor manufacturing process, improvement of the CMP process to maintain low dishing and low erosion, and solving of oxidation or contamination problems between processes are very important.

### SUMMARY OF THE INVENTION

It is an object of the present invention to provide a chemical mechanical planarization method and apparatus in a semiconductor manufacturing process capable of improving a CMP process to minimize dishing and erosion issues and controlling the distribution of charged particles in a slurry by applying an electric field to the surface of a wafer using an electrophoretic phenomenon to achieve planarization.

It is another object of the present invention to provide a chemical mechanical planarization method and apparatus in a semiconductor manufacturing process capable of solving oxidation and contamination issues that may occur in the process of successively performing a CMP process and a plating process.

In accordance with one aspect of the present invention, the above and other objects can be accomplished by the provision of a chemical mechanical planarization method in a semiconductor manufacturing process, wherein the chemical mechanical planarization method is performed to apply an electric field to the surface of a wafer using an electrophoretic phenomenon during a chemical mechanical planarization (CMP) process in order to control the distribution of charged particles in a slurry.

In accordance with another aspect of the present invention, there is provided a chemical mechanical planarization apparatus in a semiconductor manufacturing process, wherein the chemical mechanical planarization apparatus includes CMP equipment configured to perform a CMP process of planarizing the surface of a wafer and an electric field application controller configured to apply an electric field to the surface of the wafer during the CMP process.

The electric field may be applied perpendicular to the surface of the wafer to change the distribution of ions in the slurry according to the potential difference between a metal and an insulator, thereby adjusting the local etch rate of a metal surface.

Positively or negatively charged ions in the slurry may be concentrated on the metal surface through application of the electric field, thereby reducing the etch rate of the metal.

A plating process may be performed after the CMP process, the uniformity of the surface of the wafer may be measured after the CMP process and the plating process, and if the uniformity is equal to or less than a reference level, additional plating and CMP processes may be repeated. The plating process may include at least one of an electrolytic plating process and an electroless plating process.

If the height difference (h0−h1) of the surface of the wafer measured after the plating process and the CMP process is equal to or less than a reference value, the plating process may be stopped and the CMP process may be performed when the α coefficient (Wᵤₚ/W_{original}), which is the ratio of the surface width before plating to the surface width after plating, is 0.99 or less.

Voltage may be applied such that no current flows on the surface of the wafer to form an electric field, and the movement of the charged particles in the slurry through the electric field may be adjusted to control the etch rate of the surface of the wafer.

The etch rate of the surface of the wafer may be adjusted by applying current to the surface of the wafer through a conductive substrate to form a potential difference, thereby generating an electric field.

Negatively charged ions in the slurry may be concentrated on the metal surface by the electrophoretic phenomenon to reduce the etch rate of the metal.

The CMP process may be performed in an inert gas atmosphere.

The chemical mechanical planarization method may include a standby step of applying no electric field, wherein the electric field application step and the standby step may be periodically repeated.

The distribution of the electric field may be controlled so as to have symmetrical non-uniformity with respect to the center of the surface of the wafer.

The etch rate may be adjusted by applying different electric fields to a region with high metal area density and a region with low metal area density.

An electroless plating process may be further performed on a specific region of the surface of the wafer.

Mechanical polishing may be performed on the surface of the wafer after the electroless plating process.

A quantum superconductor material used in semiconductor devices for quantum technology may be any one of Nb, Sn, Al, Zn, Ta, Nb—Ti, Nb₃Sn, V₃Si, V₃Ga, Nb₃Ge, MgB₂, YBCO, BSCCO, iron pnictides, LBCO, iron chalcogenides, TBCCO, Hg-1223, and iron-based superconductors or a mixture of two or more thereof.

### BRIEF DESCRIPTION OF THE DRAWINGS

FIG. 1A is a schematic view showing the profile of a semiconductor device before a conventional CMP process;

FIG. 1B is a schematic view showing a surface after an ideal CMP process;

FIG. 1C is a schematic view showing dishing and erosion phenomena caused by a CMP process;

FIG. 2 is a schematic view illustrating the principle of an electrophoretic phenomenon according to an embodiment of the present invention;

FIG. 3 is a flowchart showing a chemical mechanical planarization method in a semiconductor manufacturing process according to an embodiment of the present invention;

FIGS. 4A, 4B, 4C, 4D, and 4E are schematic views showing the process according to the embodiment of FIG. 3;

FIG. 5 is a flowchart showing a chemical mechanical planarization method in a semiconductor manufacturing process according to another embodiment of the present invention;

FIGS. 6A, 6B, 6C, 6D, 6E, 6F, and 6G are schematic views showing the process according to the embodiment of FIG. 5;

FIG. 7 is a flowchart showing a chemical mechanical planarization method in a semiconductor manufacturing process according to another embodiment of the present invention;

FIGS. 8A and 8B are schematic views showing the profile of a semiconductor device according to an embodiment of the present invention;

FIG. 9 is a schematic view showing principal parts of a chemical mechanical planarization apparatus in a semiconductor manufacturing process according to an embodiment of the present invention; and

FIGS. 10A, 10B, 10C, and 10D are schematic views showing various embodiments in which an electric field is applied to a wafer by the chemical mechanical planarization apparatus in the semiconductor manufacturing process according to the embodiment of the present invention.

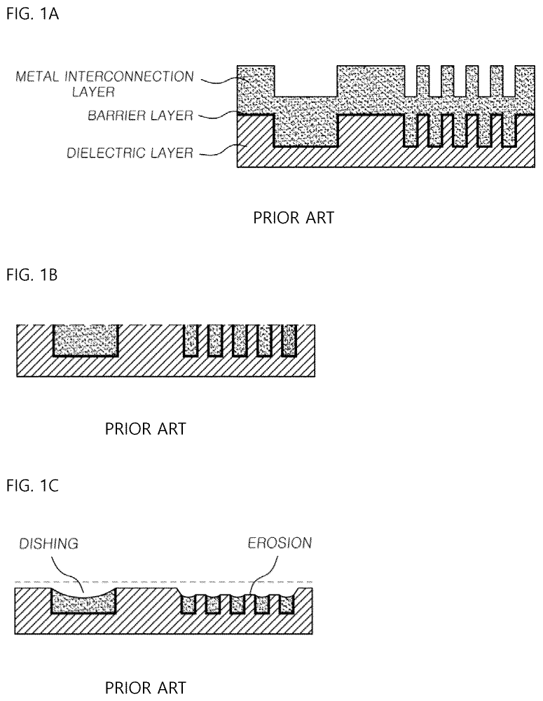

### DETAILED DESCRIPTION OF THE PREFERRED EMBODIMENTS

The present invention relates to a chemical mechanical planarization method and apparatus in a semiconductor manufacturing process capable of improving a CMP process in the semiconductor manufacturing process to minimize dishing and erosion issues and to achieve high level planarization and solving oxidation and contamination problems that may occur when the CMP process and a plating process are successively carried out.

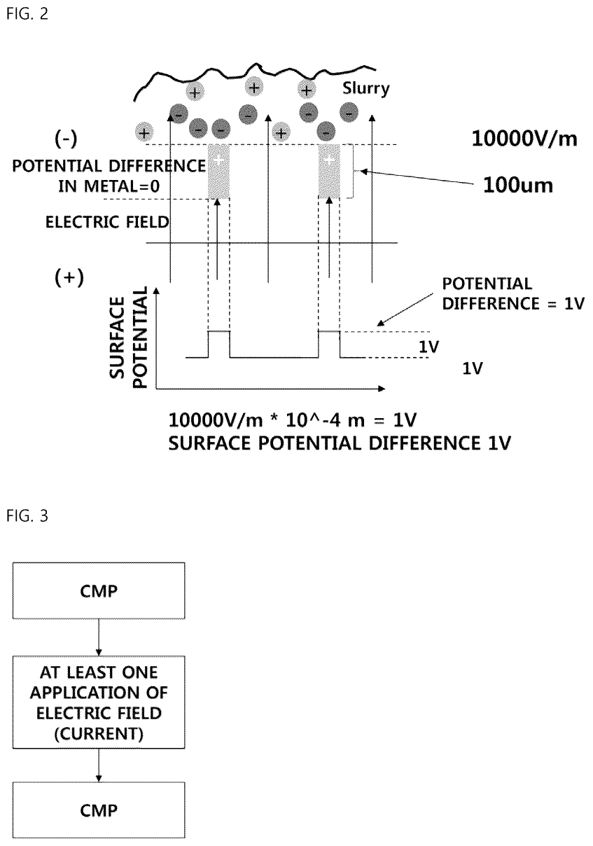

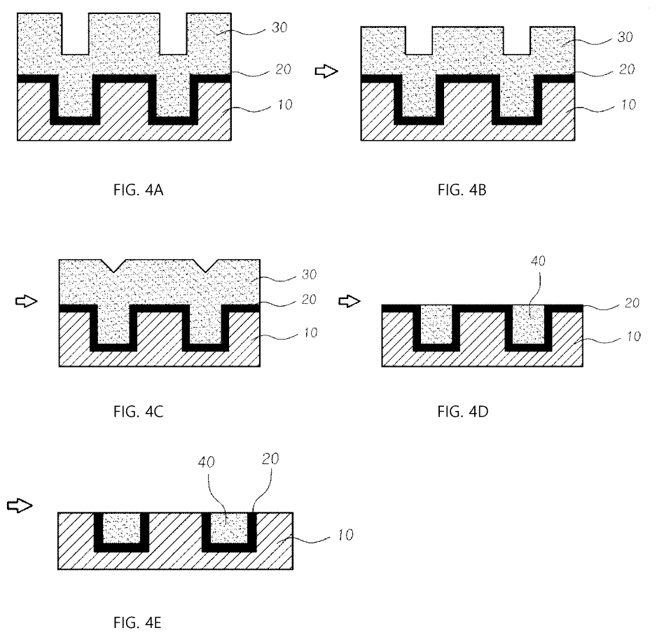

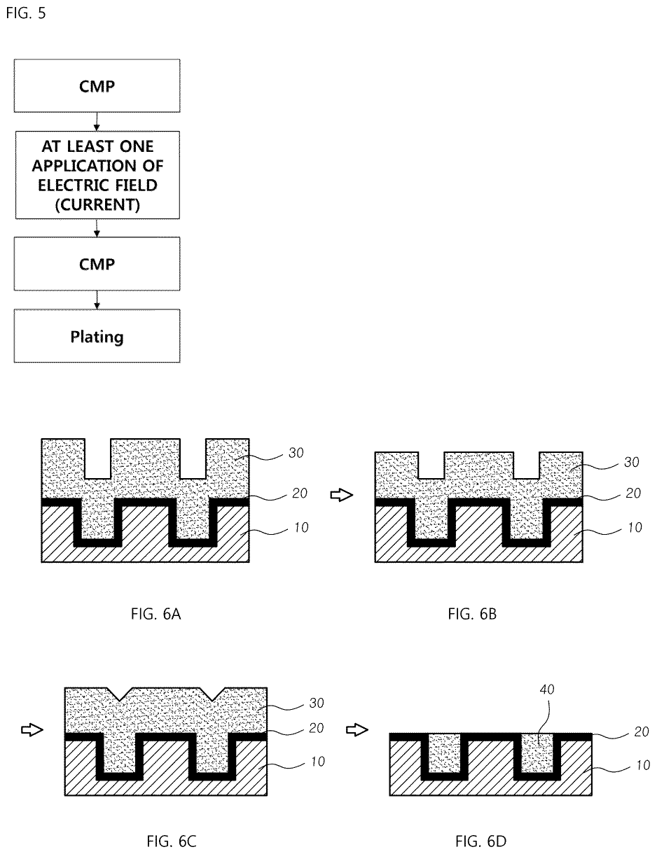

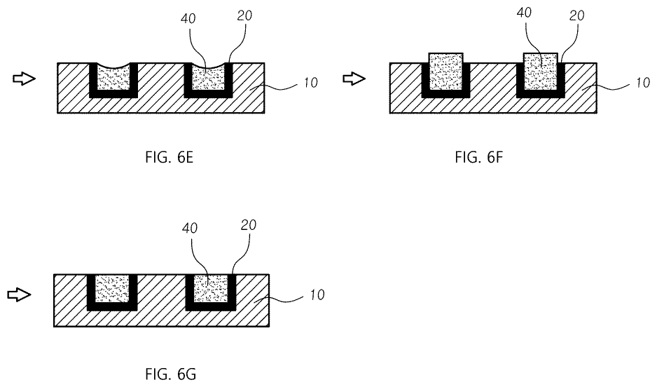

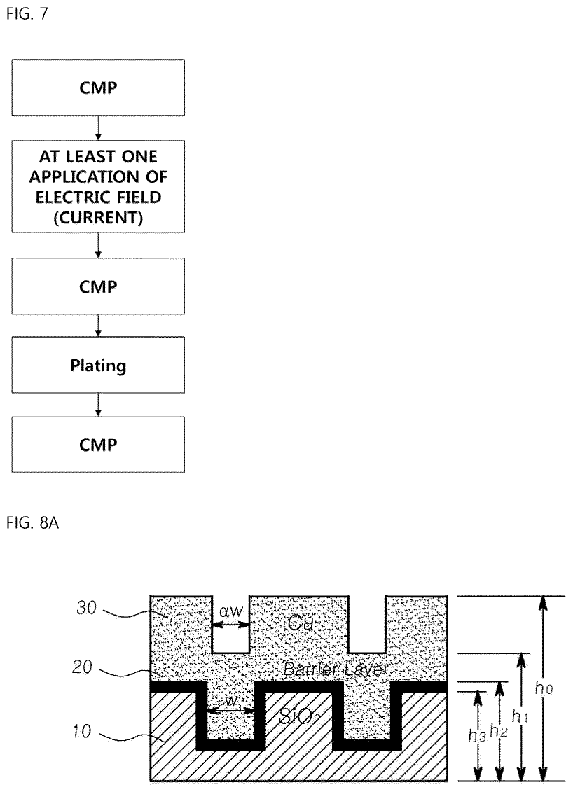

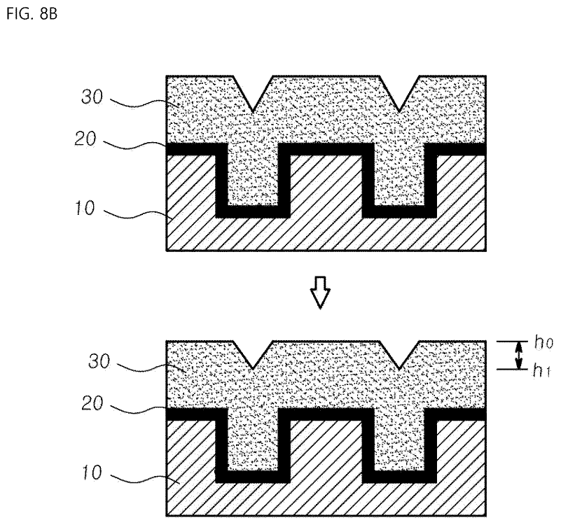

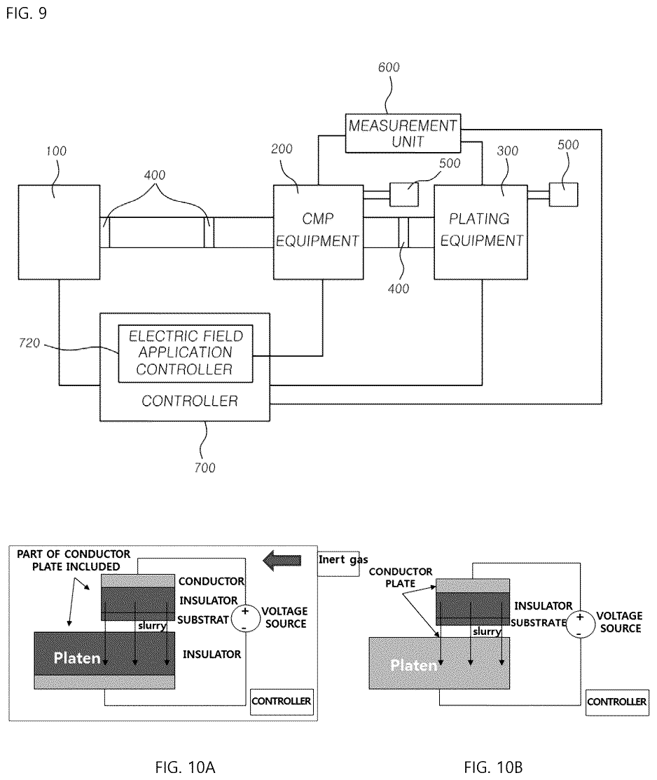

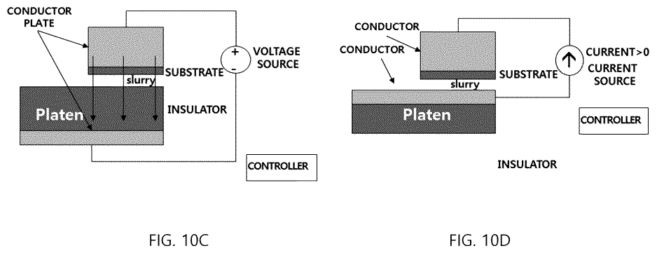

Hereinafter, embodiments of the present invention will be described in detail with reference to the accompanying drawings. FIG. 2 is a schematic view illustrating the principle of an electrophoretic phenomenon according to an embodiment of the present invention, FIG. 3 is a flowchart showing a chemical mechanical planarization method in a semiconductor manufacturing process according to an embodiment of the present invention, FIGS. 4A, 4B, 4C, 4D, and 4E are schematic views showing the process according to the embodiment of FIG. 3, FIG. 5 is a flowchart showing a chemical mechanical planarization method in a semiconductor manufacturing process according to another embodiment of the present invention, FIGS. 6A, 6B, 6C, 6D, 6E, 6F, and 6G are schematic views showing the process according to the embodiment of FIG. 5, FIG. 7 is a flowchart showing a chemical mechanical planarization method in a semiconductor manufacturing process according to another embodiment of the present invention, FIGS. 8A and 8B are schematic views showing the profile of a semiconductor device according to an embodiment of the present invention, FIG. 9 is a schematic view showing principal parts of a chemical mechanical planarization apparatus in a semiconductor manufacturing process according to an embodiment of the present invention, and FIGS. 10A, 10B, 10C, and 10D are schematic views showing various embodiments in which an electric field is applied to a wafer by the chemical mechanical planarization apparatus in the semiconductor manufacturing process according to the embodiment of the present invention.

As shown in FIGS. 2 to 7, a chemical mechanical planarization method in a semiconductor manufacturing process according to an embodiment of the present invention is performed to apply an electric field to the surface of a wafer using an electrophoretic phenomenon during a chemical mechanical planarization (CMP) process in order to control the distribution of charged particles in a slurry.

In addition, as shown in FIGS. 2 to 7, a chemical mechanical planarization apparatus in a semiconductor manufacturing process according to an embodiment of the present invention includes CMP equipment configured to perform a CMP process of planarizing the surface of a wafer and an electric field application controller configured to apply an electric field to the surface of the wafer during the CMP process.

In the present invention, therefore, it is possible to minimize dishing and erosion phenomena in the CMP process and to achieve uniform planarization of the surface of the wafer. In addition, it is possible to prevent oxidation and contamination that may occur during the process through repeated electric field application and standby steps, an electrolytic/electroless plating process, and the supply of inert gas. This may enable high-quality manufacturing of quantum devices, which may provide superior performance in applications such as quantum computing and quantum communication, including high-speed signal transmission and reduced energy loss.

In an embodiment of the present invention, it is possible to apply an electric field to the surface of a wafer using an electrophoretic phenomenon during a chemical mechanical planarization (CMP) process in order to control the distribution of charged particles in a slurry. This is performed to apply the electric field to the surface of the wafer in order to control the distribution of charged particles in the slurry and to control the etch rate. That is, it is possible to achieve the high degree of planarization required in quantum devices by applying the electric field to the surface of the wafer.

Chemical mechanical planarization (CMP) is used to planarize a wafer having a multilayered structure in a semiconductor manufacturing process. This is a method of polishing the surface of a wafer in the state in which a polishing pad and a slurry (a polishing agent containing fine particles) are in contact with the surface of the wafer. At this time, charged particles (cations, anions, etc.) in the slurry are moved in response to an electric field, which is called an electrophoretic phenomenon. When the electric field is applied to the surface of the wafer, the charged particles in the slurry may be moved to increase or decrease the polishing speed of a specific region. This phenomenon may be used to obtain a uniform surface by adjusting the etch rate for a specific region of the wafer.

For example, if there is a large height difference between the region of a metal layer to be planarized and an insulating layer, the electric field may be applied to the metal layer such that the metal layer can be intensively etched. This minimizes problems commonly encountered in the CMP process, such as dishing and erosion.

FIG. 2 is a schematic view illustrating the principle of an electrophoretic phenomenon according to an embodiment of the present invention, wherein a process of controlling the distribution of charged particles in a slurry by applying an electric field during a chemical mechanical planarization (CMP) process in a semiconductor manufacturing process is shown. That is, a method of controlling the etch rate of the surface of a wafer using an electrophoretic phenomenon in order to effectively perform planarization in the CMP process is described.

As shown, an electric field is formed on the surface of the wafer, and the electric field induces the movement of charged particles in the slurry. In order to generate the electric field, voltage is applied between the surface of the wafer and a structure located thereunder. The potential difference is about 1 V, and the electric field on the surface of the wafer is calculated to be about 10,000 V/m. This electric field serves to induce the movement of charged particles in the slurry. That is, the intensity of the electric field is 10,000 V/m, which is calculated based on a potential difference having the height difference of 100 μm from the surface of the wafer. Since the intensity of the electric field is 10,000 V/m and the distance is 10\hat{ }⁻⁴ m (100 μm), the potential difference is calculated to be 1 V.

The slurry contains a mixture of positively charged (+) and negatively charged (−) particles. In the figure, there are positively charged particles (+) colored in red and negatively charged particles (−) colored in blue. The electric field causes the positively charged particles to move toward a negative (−) electrode and the negatively charged particles to move toward a positive (+) electrode. This movement of particles changes the distribution of charged particles in the slurry, which in turn adjusts the etch rate at a specific position.

In addition, the figure shows that the electric field is applied in a vertical direction. An electric field is generated perpendicularly between the surface of the wafer and the electrode thereunder, and the electric field plays an important role in controlling the local etch rate of the surface of the wafer. In addition, the potential difference provides energy required for etching and polishing processes on the surface of the wafer, and as the potential difference increases or decreases, the movement of charged particles may be accelerated or decelerated.

As such, the positively and negatively charged particles in the slurry are distributed on the surface of the wafer by the electric field, which controls the etch rate. As the positively charged particles move toward the negative (−) electrode and the negatively charged particles move toward the positive (+) electrode, the concentration and distribution of charged particles in the slurry affects the surface of the wafer.

The surface of the wafer has a local potential difference generated by the electric field, which controls the etch rate in each region. This is used as a method of adjusting the degree of etching and planarization in a specific region of the surface of the wafer, and problems such as dishing and erosion may be solved by controlling the local etch rate.

In addition, if the overall distribution is uniform or is formed so as to have a specific pattern, the etch rate of the surface of the wafer is adjusted accordingly. This may reduce the non-uniformity of the surface of the wafer and optimize the degree of planarization.

In addition, according to the embodiment of the present invention, the electric field is applied perpendicular to the surface of the wafer to change the distribution of ions in the slurry according to the potential difference between the metal and the insulator, thereby adjusting the local etch rate of the metal surface.

The electric field applied perpendicular to the surface of the wafer generates the potential difference between the metal and the insulator. This potential difference induces the movement of charged particles in the slurry to adjust the polishing rate of the surface. The potential difference between the metal layer and the insulating layer serves to attract certain ions to a specific region, increasing or decreasing the polishing rate in the region. This allows for precise adjustment of the height of the surface.

For example, if the metal surface needs to be polished more than the insulator, the potential difference may be made higher to concentrate the charged particles in the slurry onto the metal surface. This increases the etch rate of the metal surface and decreases the etch rate of the insulator, allowing for more effective planarization.

In addition, according to the embodiment of the present invention, application of the electric field allows positively or negatively charged ions in the slurry to be concentrated on the metal surface, thereby reducing the etch rate of the metal.

In the CMP process, the concentration of negatively or positively charged ions in the slurry greatly affects the etch rate of the surface. At this time, when the electric field is applied, specific ions may be concentrated on the metal surface of the wafer, thereby adjusting the etch rate of the metal layer. This prevents dishing of the surface and reduces over-etching.

For example, when polishing a copper (Cu) metal layer, the concentration of positively charged ions in the slurry inhibits chemical reaction on the metal surface, resulting in a lower etch rate. This allows the metal layer to be controlled so as not to be excessively etched.

In addition, according to the embodiment of the present invention, a plating process is performed after the CMP process, after which the uniformity of the surface of the wafer is measured and if the uniformity is equal to or less than a reference level, additional plating and CMP processes are repeated.

If the surface is not sufficiently planarized due to problems such as dishing or erosion in the CMP process, the plating process is performed to remove the difference in height of the surface of the wafer and the CMP process is performed again, thereby improving the final flatness of the surface of the wafer through such repeated processes.

This has the effect of improving the signal transmission efficiency and electrical properties of semiconductor devices. For example, if a metal interconnection layer is unevenly etched after the CMP process, the surface of the wafer is realigned by additional plating and then polished uniformly by CMP again.

In addition, according to the embodiment of the present invention, the plating process includes at least one of electrolytic plating or electroless plating.

Electrolytic plating is a process of depositing metal ions on the surface of the wafer using current, and has the advantage of quickly depositing a thick metal layer. On the other hand, electroless plating is a process in which metal ions are reduced and deposited on the surface by chemical reaction without current, allowing for uniform plating. An appropriate one of the two methods may be selected, and the plating may be performed according to the state of planarization of the surface of the wafer.

For example, electrolytic plating is used to rapidly increase the thickness of the metal interconnection layer, whereas electroless plating is used when a uniform plating layer is required.

In addition, according to the embodiment of the present invention, if the height difference (h0−h1) of the surface of the wafer measured after the CMP process and the plating process is equal to or less than a reference value, the plating process is stopped and the CMP process is performed when the α coefficient (Wᵤₚ/W_{original}) is 0.99 or less.

The α coefficient indicates the ratio of the surface width before plating to the surface width after plating. If this ratio is 0.99 or less, this indicates that planarization of the surface has been completed and no further plating is required. At this time, the plating process is stopped and switched to the CMP process to increase process efficiency. This minimizes dishing and erosion of the surface and optimizes the flatness of the surface of the wafer during repeated processes.

In addition, according to the embodiment of the invention, voltage is applied such that no current flows to form an electric field, which adjusts the movement of charged particles in the slurry.

By applying voltage instead of current, only the electric field is formed to control the movement of charged particles in the slurry. This method prevents electrical damage during the etching process because there is no direct current impact on the surface. In addition, this allows the etch rate of a specific region to be adjusted (see FIGS. 10A, 10B, and 10C).

In addition, according to the embodiment of the present invention, an electric potential is formed by applying current to the surface of the wafer through a conductive substrate, thereby generating an electric field. The electric potential may be formed on the surface of the wafer and the electric field may be generated by directly applying current to the surface of the wafer using the conductive substrate. This is effective for locally adjusting the etch rate in a specific region through the adjustment of the electric field (see FIG. 10D).

In addition, according to the embodiment of the present invention, negatively charged ions in the slurry may be concentrated on the metal surface by an electrophoretic phenomenon to reduce the etch rate of the metal.

In the CMP process, the type and distribution of charged particles in the slurry have an important influence on the etch rate of the surface. By applying the electric field to control the negatively charged ions in the slurry so as to be concentrated on the metal surface, excessive etching of the metal layer is prevented. This method is effective in minimizing a dishing phenomenon by preventing excessive polishing of the metal layer. This prevents unnecessary etching while maintaining a uniform metal layer.

For example, when the electric field is applied to a region in which the metal surface is exposed to concentrate negatively charged ions in the slurry, chemical reaction on the metal surface is inhibited, resulting in a lower etch rate.

In addition, according to the embodiment of the present invention, the CMP process is performed in an inert gas atmosphere in order to prevent oxidation of the surface of the wafer. Negative effects such as oxidation of the surface of the wafer may occur. When the process is performed in an inert gas atmosphere (e.g., argon, helium, or nitrogen) in order to prevent this, it is possible to prevent contact with oxygen, thereby preventing oxidation and contamination of the metal layer. This keeps the surface of the wafer flat and stabilizes the electrical properties of the surface. For example, the use of argon gas in a CMP process for a copper (Cu) plating layer inhibits the formation of an oxide during the process, resulting in higher quality planarization.

In addition, according to the embodiment of the present invention, the method includes a standby step of applying no electric field, and the electric field application and standby steps are repeated periodically. Periodically repeating the electric field application step and the standby step is more effective in achieving uniform surface planarization than continuously applying the electric field to the surface of the wafer during the CMP process. While no electric field is applied, the particles in the slurry may move freely and adjust the overall distribution thereof. This periodic application of the electric field allows for overall uniform polishing rather than concentrating in a specific region.

For example, the electric field may be applied for a period of time to concentrate the charged particles in a specific region of the surface, and then the standby step may be performed to naturally rearrange the particle distribution again for a more uniform planarization process.

In addition, the distribution of the electric field is controlled so as to have symmetrical non-uniformity with respect to the center of the surface of the wafer. The symmetrical non-uniformity of the electric field distribution has a significant impact on the efficiency of the CMP process depending on the characteristics of the surface. Uniform etching over the entirety of the surface is achieved by controlling the electric field distribution symmetrically with respect to the center of the surface of the wafer. This may prevent local over-etching or under-etching.

For example, the effect of the electric field is efficiently controlled by distributing the intensity of the electric field differently according to a specific pattern on the surface of the wafer.

In addition, according to the embodiment of the present invention, the etch rate is adjusted by differently applying the electric field to a region with high metal area density and a region with low metal area density. In the CMP process, the etch rate varies depending on the area density of the metal, and in order to control this, the electric field is differently applied to the region with high metal area density and the region with low metal area density. The electric field distribution is controlled such that the region with high metal area density has a lower etch rate and the region with low metal area density has a higher etch rate to ensure uniform planarization.

For example, the electric field is applied to the region with high metal area density to concentrate charged particles in the slurry, thereby increasing the etch rate of the region, and the electric field is weakened in the region with low metal area density to decrease the etch rate, thereby achieving a uniform surface.

In addition, according to the embodiment of the present invention, an electroless plating process is additionally performed on a specific region of the surface of the wafer. If non-uniformity remains even after the CMP process, the electroless plating process is performed on the region to adjust the height difference of the surface. Electroless plating may deposit metal ions on the surface by chemical reaction without current, allowing the metal to be added uniformly only to a specific region.

For example, a metal layer may be deposited only in a specific region where the metal layer is not flat by electroless plating and then the CMP process is performed again to form an overall uniform surface.

In addition, according to the embodiment of the present invention, mechanical polishing is performed on the surface of the wafer after the electroless plating process. After the height of a specific region by electroless plating is adjusted, the plating layer is planarized by mechanical polishing. Although electroless plating is effective in resolving local non-uniformity, the final planarization of the surface after plating is preferably accomplished by mechanical polishing. That is, the metal is deposited only in a specific region of the surface of the wafer by electroless plating, and then the region is polished such that the height of the region coincides with the height of the surroundings thereof.

In addition, a quantum superconductor material used in the semiconductor device for quantum technology according to the embodiment of the present invention may be constituted by various metals or superconductor materials.

Specifically, one or more of Nb, Sn, Al, Zn, Ta, Nb—Ti, Nb₃Sn, V₃Si, V₃Ga, Nb₃Ge, MgB₂, YBCO, BSCCO, iron pnictides, LBCO, iron chalcogenides, TBCCO, Hg-1223, and iron-based superconductors may be used.

Semiconductor devices used in quantum computing, quantum communication, etc. require very high electrical properties and stability. To this end, superconducting materials such as niobium (Nb), tin (Sn), and aluminum (Al) are used, wherein these materials have low resistance and fast signal transfer characteristics. Special care is required when handling these materials in the CMP process, and uniform and precise planarization may optimize the performance of the device.

For example, Nb₃Sn is a material with high conductivity and superconducting properties, which may be used in interconnection of quantum devices. The CMP process may be used to planarize the surface of the material and to maintain a uniform thickness in order to increase the efficiency of the device. Devices for quantum technology use superconducting materials that are highly conductive and stable in nature. Here, various metals, alloys, and compound superconductors are mentioned, each of which may be selected depending on the characteristics of the quantum device. These materials exhibit superconducting properties at very low temperatures and are essential for the fast and accurate transfer of information in quantum computing and quantum communication.

For example, yttrium barium copper oxide (YBCO) is a superconductor with a high threshold temperature, which is suitable for signal transmission in quantum devices, and slurry selection and field application conditions are important when planarizing the surface of the material through the CMP process.

The chemical mechanical planarization apparatus in the semiconductor manufacturing process according to the embodiment of the present invention is an apparatus for performing chemical mechanical planarization, and includes CMP equipment configured to perform a CMP process and an electric field application controller configured to apply an electric field to the surface of a wafer.

According to the embodiment of the present invention, the apparatus serves to adjust the distribution of charged particles and to control the etch rate of the surface of the wafer by applying the electric field during the CMP process. The apparatus improves the uniformity of etching and minimizes dishing and erosion by concentrating the electric field on a specific region of the surface of the wafer through the electric field application controller. The apparatus provides higher precision in the planarization of the surface of the wafer since the controller capable of applying the electric field is added, unlike general CMP equipment.

For example, an electric field may be applied to the surface of a wafer having a specific pattern such that charged particles in a slurry can be concentrated in a metal region to adjust local etch rates.

In addition, the electric field application controller according to the embodiment of the present invention applies the electric field perpendicular to the surface of the wafer to form a potential difference between a metal and an insulator. This controls the distribution of ions in the slurry.

Applying a perpendicular electric field during the CMP process may control the distribution of charged particles in the slurry, thereby adjusting the etch rate of the surface of the wafer. In particular, the etch rate changes depending on the potential difference between the metal and the insulator, which may be appropriately adjusted to improve the uniformity of the surface.

For example, the electric field may be applied perpendicular to the surface of the wafer such that less etching occurs on the insulator surface and more etching occurs on the metal surface to achieve uniform planarization.

According to the embodiment of the present invention, the application of the electric field causes the concentration of negatively or positively charged ions on the surface of the wafer to reduce the etch rate of the metal. Etching by chemical reaction is inhibited by concentrating negatively or positively charged ions in the slurry on the metal surface. This prevents excessive etching of the metal surface and maintains stable etching of the metal surface. This method is effective in inhibiting a dishing phenomenon of a metal line in CMP processes.

For example, positively charged ions in the slurry are concentrated on the metal surface by applying the electric field, which inhibits metal etching and forms a uniform metal line.

In addition, according to the embodiment of the present invention, the apparatus includes a measurement unit configured to perform a plating process on the surface of the wafer after the CMP process, to measure the uniformity of the surface of the wafer after the CMP and plating processes, and to perform additional plating and CMP processes if the uniformity is equal to or less than a reference level. The CMP process and the plating process are alternately performed to increase the uniformity of the surface of the wafer. The uniformity of the surface after the processes is measured to determine whether additional processes are required, and if required, plating and CMP may be additionally performed to achieve desired surface flatness. This process is especially important for quantum devices that require a high degree of planarization.

For example, after CMP, the height difference of the surface is measured using a measurement device, and if the height difference is equal to or less than a reference value, the height is corrected through an additional plating process, and then final CMP is performed.

In addition, according to the embodiment of the present invention, the apparatus includes at least one of electrolytic plating equipment or electroless plating equipment configured to perform a plating process. Electrolytic plating is the deposition of metal ions on the surface of the wafer using current, whereas electroless plating deposits a metal through chemical reaction. An appropriate one of the two methods may be selected and used, or a combination of the two processes may be used to perform plating. This ensures that the thickness of the metal on the surface of the wafer is uniform and that the wafer is planarized.

For example, electrolytic plating is performed in an electrically conductive region, and electroless plating is performed in a region that has a complex structure or is not conductive, to make the surface uniform.

In addition, the electric field application controller according to the embodiment of the present invention applies voltage such that no current flows on the surface of the wafer to form an electric field. This adjusts the movement of charged particles in the slurry to control the etch rate.

An electric field is formed by applying voltage that prevents the flow of current, which adjusts the movement of charged particles in the slurry. This method may effectively adjust the etching of the surface while minimizing contamination or damage caused by current. For example, voltage is applied to the surface of the wafer such that the charged particles in the slurry are not concentrated at a specific position, thereby maintaining a uniform etch rate.

In addition, the electric field application controller according to the embodiment of the present invention applies current to the surface of the wafer through the conductive substrate to form an electric potential and locally generates an electric field to adjust the etch rate of the surface of the wafer.

By applying current directly to the surface of the wafer through the conductive substrate, a potential difference is formed and a local electric field is generated. The local electric field controls the movement of ions in the slurry, allowing the etch rate to be adjusted. This may inhibit or promote etching in a specific region, and allows for uniform planarization of the surface of the wafer in the CMP process. By generating a local potential difference, the etch rate may be finely adjusted so as to correspond to different surface patterns.

For example, when a local electric field is formed by applying current to the metal surface in a specific region, ions in the slurry are concentrated in the region, increasing or decreasing the local etch rate.

In addition, the electric field application controller according to the embodiment of the present invention performs control such that negatively charged ions in the slurry are concentrated on the metal surface by an electrophoretic phenomenon. The electric field application controller performs control such that the negatively charged ions in the slurry are concentrated on the metal surface using the electrophoretic phenomenon. As a result, it is possible to reduce or adjust the etch rate of the metal surface. Electrophoresis is a phenomenon in which charged particles are moved by an electric field, which may be used to concentrate ions in the slurry at a specific position. This prevents excessive etching of the metal surface and enables uniform polishing.

For example, when the electric field is applied during the CMP process, negatively charged ions in the slurry move to the metal surface to reduce the etch rate of the surface, which may reduce dishing.

In addition, the apparatus includes an inert gas supply unit configured to perform a CMP process in an inert gas atmosphere in order to prevent oxidation of the surface of the wafer during the CMP process.

A device configured to supply an inert gas is needed to prevent oxidation of the surface of the wafer during the CMP process. The inert gas may be constituted by He, Ar, N₂, or the like with low chemical reactivity, and oxidation and contamination of the surface are prevented by performing the process in such an atmosphere. Particularly, in processes that require high precision, such as semiconductor devices for quantum technology, this anti-oxidation technology is essential to maintain surface quality.

For example, an oxidation prevention gas is injected into the CMP equipment through the inert gas supply unit to minimize oxidation of the surface of the wafer during the process.

In addition, according to the embodiment of the present invention, the inert gas includes at least one of He, Ar, Ne, Kr, and N₂. The inert gas used in the CMP process is used to prevent oxidation of the surface of the wafer and to provide a clean environment. The atmosphere in the equipment is maintained using at least one of He, Ar, Ne, Kr, and N₂ to prevent oxidation or contamination of the metal layer during CMP. When the inert gas is selected and used, an appropriate atmosphere may be formed based on the properties of each gas and the material of the wafer.

For example, the interior of the CMP equipment is maintained in an N₂ atmosphere using N₂ gas in order to prevent oxidation of the metal surface.

In addition, according to the embodiment of the present invention, the electric field application controller controls the distribution of the electric field to have symmetrical non-uniformity with respect to the center of the surface of the wafer. When the electric field is applied to the surface of the wafer, the electric field application controller controls the distribution to be symmetrically non-uniform with respect to the center of the surface of the wafer. This symmetrical distribution of the electric field assists in uniform etching during the wafer planarization process and reduces defects that may be caused by uneven etching. This non-uniform distribution of the electric field is used to avoid concentrated etching only in a specific region while maintaining the uniform distribution of the electric field. For example, a certain pattern of a metal line may be more precisely etched by varying the electric field over the edge and the center of the surface of the wafer.

In addition, according to the embodiment of the present invention, the electric field application controller applies different electric fields to a region with high metal area density on the surface of the wafer and a region with low metal area density on the surface of the wafer to adjust the etch rate. The etch rate is adjusted by differently applying the electric field depending on the area density of the metal formed on the surface of the wafer. By applying different electric fields to a part having a large metal area and a part having a small metal area, it is possible to maintain the uniformity of etching and to prevent excessive polishing of a specific region. This ensures that the entire surface is uniformly planarized and that the line thickness is uniform. For example, a low electric field may be applied to the region with high metal area density and a high electric field may be applied to the region with low metal area density to achieve overall uniform etching.

In addition, according to the embodiment of the present invention, the electric field application controller adjusts the etch rate of the surface of the wafer by periodically repeating an electric field application step and a standby step of applying no electric field. That is, the electric field application controller adjusts the etch rate by periodically repeating the electric field application step and the standby step, rather than continuously applying the electric field. This allows for fine adjustment of the etch rate of a specific region of the surface of the wafer and prevents excessive etching or contamination. Because the movement of charged particles is stopped or slowed down in the standby step, the etch rate and uniformity in the electric field application step may be effectively controlled.

For example, the uniform etch rate of the entire surface may be maintained by applying an electric field for a certain period of time followed by a certain standby step.

In addition, according to the embodiment of the present invention, the electric field application controller controls the intensity and direction of the electric field so as to change over time, thereby adjusting the etch rate of a specific region of the surface of the wafer. The ability to adjust the intensity and direction of the electric field over time controls the etch rate of the surface of the wafer. This method periodically adjusts the intensity and direction of the electric field to prevent uneven etching on the surface of the wafer. If intensive etching is required in a specific region, the intensity of the electric field may be increased or the direction of the electric field may be focused to a specific part, and conversely, the electric field may be weakened to reduce the etch rate. This makes it possible to respond sensitively to local shape changes on the surface of the wafer and achieve desired planarization. For example, when the edge of the surface of the wafer needs to be etched more, the intensity of the electric field may be increased and the direction of the electric field may be adjusted to concentrate the etching effect on the part.

In addition, according to the embodiment of the present invention, the electric field application controller serves to finely adjust the distribution of the electric field and the direction of current in order to locally adjust the etch rate of the surface of the wafer. The electric field application controller locally adjusts the distribution of the electric field in order to finely adjust the etch rate for a specific region of the wafer. In addition, the electric field application controller may precisely control the movement of the charged particles in the slurry by finely adjusting the direction of the current. This control enables fine planarization, such as increasing or decreasing the etch rate in a specific region, and supports uniform etching of the surface of the wafer. For example, if the pattern of the wafer is complex, the electric field application controller delicately adjusts the direction and intensity of the current to perform etching corresponding to the complex pattern.

In addition, a quantum superconductor material used in semiconductor devices for quantum technology may be constituted by any one of Nb, Sn, Al, Zn, Ta, Nb—Ti, Nb₃Sn, V₃Si, V₃Ga, Nb₃Ge, MgB₂, YBCO, BSCCO, iron pnictides, LBCO, iron chalcogenides, TBCCO, Hg-1223, and iron-based superconductors or a mixture of two or more thereof.

The superconducting material required in semiconductor devices for quantum technology requires high electrical conductivity, low resistance, and properties that enable rapid signal transmission. The presented materials possess these properties and enable efficient operation of quantum devices. The use of the superconductor, especially in quantum computing and communications, minimizes energy losses, speeds up signal transmission, and plays an important role in improving device performance. For example, Nb₃Sn has a high threshold current, and high-temperature superconductors, such as YBCO, are suitable for interconnection of quantum computers that require high-speed operation.

In addition, according to the embodiment of the present invention, a protective film may be formed on the surface of the wafer after the plating and CMP process to prevent oxidation remaining on the surface of the wafer after the CMP process. After the CMP process, the protective film is formed to prevent the metal line on the surface of the wafer from reacting with oxygen in the air and oxidizing. The protective film is generally made of an antioxidant material and prevents the metal layer from coming into contact with moisture or oxygen in the air. This allows the electrical properties and surface condition of the metal line on the surface of the wafer to remain stable. For example, a protective film, such as SiO₂ or Si₃N₄, is deposited on the metal surface to prevent oxidation.

In addition, according to the embodiment of the present invention, the electric field application controller may finely adjust the distribution of the electric field and the direction of the current in order to locally control the etch rate of the surface of the wafer. The electric field application controller delicately adjusts the distribution of the electric field and the direction of the current to finely adjust the etch rate in a specific region. As a result, it is possible to maintain uniform planarization of the surface of the wafer and to selectively induce etching only at the part where etching is needed. For example, the intensity and direction of the electric field are adjusted so that appropriate etching can be performed on each part of the wafer even when the specific pattern structure of the wafer or the size of a pad varies. In addition, when fine polishing is required on a specific part of the wafer, the etch rate may be precisely controlled by focusing the direction of the current to the part and adjusting the intensity of the electric field.

In addition, according to the embodiment of the present invention, the electric field application controller controls the intensity and direction of the electric field so as to change over time, thereby adjusting the etch rate of a specific region of the surface of the wafer. This is a method of adjusting the etch rate by controlling the intensity and direction of the electric field that changes over time. This is useful when it is necessary to change or adjust the etch rate of a specific part of the surface of the wafer. Varying the electric field over time changes the etch rate or the etching shape, which may be used to intensively adjust the etching on a specific part. For example, if a higher etch rate is desired in the center of the wafer, the electric field may be intensively applied to the region at regular time intervals.

In addition, according to the embodiment of the present invention, the electric field application controller may periodically repeat the electric field application step and the standby step of applying no electric field to adjust the etch rate of the surface of the wafer. Periodically repeating the electric field application and standby steps is a method capable of precisely controlling the etch rate of the surface of the wafer.

Since continuous application of the electric field may result in excessive etching in a specific region, the etch rate of the surface of the wafer is adjusted by adjusting the application and standby cycle. This method has the advantage of controlling the local height difference of the surface and preventing damage caused by excessive etching or polishing.

For example, in order to prevent the surface of the wafer from being excessively etched during the CMP process, the surface etch rate is adjusted by periodically stopping application of the electric field, switching to the standby step, and applying the electric field again.

Hereinafter, another embodiment of the present invention will be described in detail.

A chemical mechanical planarization method in a semiconductor manufacturing process according to another embodiment of the present invention includes the steps of measuring initial topography of the surface of a wafer to measure the non-uniformity of the surface of the wafer, performing a plating process when the height difference (h0−h1) of the surface of the wafer is equal to or less than a reference value, performing a CMP process for surface planarization of the surface of the wafer, and remeasuring the uniformity of the surface of the wafer after the plating process and the CMP process to determine whether an additional plating process and an additional CMP process are required, wherein the CMP process and the plating process are repeated at least once.

During the CMP process, a process of applying an electric field to the surface of the wafer using the electrophoretic phenomenon to control the distribution of charged particles in a slurry is performed. That is, the electrophoresis process may be performed at least once in each process, such as an initial process, an intermediate process, or a reprocess, as needed or in each process.

FIGS. 3, 5, and 7 show that an electrophoretic phenomenon is used by applying an electric field at least once during each CMP process, wherein FIG. 3 shows a process of applying an electric field (current) at least once during a CMP process, FIG. 5 shows a process of applying an electric field (current) at least once during a CMP process and performing an additional plating process, and FIG. 7 shows a process of applying an electric field (current) at least once during a CMP process, performing an additional plating process, and performing an additional CMP process.

Each process may be performed at least once as needed, and depending on the state of the surface of the wafer, the electric field application process may be performed during at least one of CMP processes, i.e., an initial CMP process, an intermediate CMP process, and a re-CMP process.

An apparatus for performing chemical mechanical planarization in a semiconductor manufacturing process according to an embodiment of the present invention includes CMP equipment 200 formed on one side of device formation equipment 100, the CMP equipment being configured to perform a CMP process of planarizing the surface of a wafer, plating equipment 300 formed on one side of the CMP equipment 200, the plating equipment being configured to perform a plating process of plating the surface of the wafer, a measurement unit 600 configured to detect non-uniformity by measuring initial topography of the surface of the wafer provided by the device formation equipment 100, a controller 700 configured to control the CMP equipment 200 and the plating equipment 300 by detecting the height difference (h0−h1) of the surface of the wafer measured by the measurement unit 600, and a transfer system configured to transfer the wafer from each of the device formation equipment 100, the CMP equipment 200, and the plating equipment 300.

According to the embodiment of the present invention, in the chemical mechanical planarization apparatus in the semiconductor manufacturing process, the function of an electric field application controller may be added to the configuration of the controller. That is, according to the embodiment of the present invention, the chemical mechanical planarization apparatus may include CMP equipment, a controller having the function of an electric field application controller, plating equipment, a measurement unit, and a transfer system.

As described above, the electric field application controller applies an electric field to the surface of the wafer during the CMP process to adjust the distribution of charged particles in a slurry and to control the etch rate. In addition, the electric field application controller adjusts the intensity, direction, application, and standby period of the electric field to optimize the flatness of the surface.

The present invention relates to a method and apparatus for repeatedly performing plating and CMP processes in a semiconductor manufacturing process, measuring the non-uniformity of the surface of a wafer, and performing additional plating and CMP processes if necessary.

In addition, in the CMP process of the present invention, the initial topology of the wafer is measured, a plating process is performed when the height difference of the surface of the wafer is equal to or less than a reference value, and the surface is planarized through the CMP process. Subsequently, the uniformity is evaluated by remeasurement and the process is repeated if necessary.

In addition, the present invention provides an apparatus for performing a process in an inert gas atmosphere in order to prevent oxidation during wafer transfer.

In the chemical mechanical planarization method in the semiconductor manufacturing process according to the embodiment of the present invention, first, the initial topography of the surface of the wafer is measured to measure the non-uniformity of the surface of the wafer.

A wafer according to an embodiment of the present invention includes at least one semiconductor device, wherein a semiconductor device is formed on a substrate by a semiconductor process, a dielectric layer 10 is formed, a barrier layer 20 is formed thereon, an interconnection metal layer (Cu) is formed thereon, and an upper part of the interconnection metal layer and the barrier layer 20 are planarized through a chemical mechanical planarization (CMP) process in order to form a metal line 40, whereby the metal line 40 is completed.

Optionally, the wafer of the present invention may also include a multilayered stack of semiconductor devices and metal lines 40. In this case, the CMP process serves to remove and planarize non-uniform surfaces between the layers in the semiconductor devices having the multilayered structure.

In a silicon semiconductor process, a material, such as Ta, TaN, TiN, Ti, W, WN, Ru, Co, CoSi₂, Ni, or NiSi, may be used as the barrier layer 20.

According to the embodiment of the present invention, the semiconductor device is for quantum technology, wherein the material constituting a main effective layer is made of a quantum superconductor material.

According to the embodiment of the present invention, the quantum superconductor material used in the semiconductor device for quantum technology is any one of Nb, Sn, Al, Zn, Ta, Nb—Ti, Nb₃Sn, V₃Si, V₃Ga, Nb₃Ge, MgB₂, YBCO (YBa₂Cu₃O₇₋ₓ), BSCCO (Bi₂Sr₂Ca₂Cu₃O₁₀), iron pnictides (e.g., Ba₁₋ₓKₓFe₂As₂), LBCO (La₂₋ₓBaₓCu_{O4}), iron chalcogenides (e.g., FeSe), TBCCO (Tl₂Ba₂Ca₂Cu₃O₁₀), Hg-1223 (HgBₐ₂Ca₂Cu₃O₈₊ₓ), iron-based superconductors (LaFeAsO, BaFe₂As₂, and SmFeAsORb₃C₆0), or a mixture of two or more thereof.

The initial topography of the surface of the wafer is measured to measure the non-uniformity of the surface of the wafer. That is, the height difference, roughness, etc. of the surface of the wafer are precisely measured to identify a non-uniform part, which is performed by the measurement unit 600 according to the embodiment of the present invention.

The measurement unit 600 configured to measure the topography of the surface of the wafer may measure the topography by measuring a change in reflectivity or the distance to the surface of the wafer using a laser or light. In addition, the measurement unit may measure the height difference and pattern change of the surface by detecting a change in capacitance between the surface of the wafer and a sensor, and in particular, may precisely measure the thickness change of the plating layer.

Here, the surface of the wafer is in the state in which the barrier layer 20 is formed on the dielectric layer 10 and the metal interconnection layer 30 is formed by the plating process, and the height of the metal interconnection layer 30 may be variously changed in response to the pattern or shape of the semiconductor device.

Meanwhile, before measuring the non-uniformity of the surface of the wafer, a preliminary CMP process may be performed. This allows a subsequent plating process or CMP process to proceed more smoothly.

If the initial state of the surface of the wafer is too non-uniform, it is difficult to complete the planarization operation by this CMP process alone, or the wafer has a large height difference, non-uniform pressure may be applied during the polishing process, which may result in non-uniform planarization. In this case, the preliminary CMP process may be performed to remove the initial non-uniformity to some extent, allowing for more precise planarization in the main CMP process.

In the embodiment of the present invention, the vertical sectional shape has a quadrangular pattern, the metal interconnection layer 30 is also formed so as to have different heights along the quadrangular pattern, and the measurement of the initial topography in the present invention is performed to detect the surface of the metal interconnection layer 30 having different heights.

FIGS. 8A and 8B show variables associated with the initial topography after the initial plating process is completed, wherein the barrier layer 20 is formed on the dielectric layer (SiO₂) 10 and the metal interconnection layer 30 is formed on the barrier layer 20 by the plating process.

As shown in FIGS. 8A and 8B, as the plating process proceeds, the upper width (Wᵤₚ—the width of the plating pattern after plating) of the surface of the wafer may be less than the lower width (W_{original}—the width of the barrier layer pattern before plating) of the surface of the wafer. As the plating process is completed, the topology may be changed, as shown in FIG. 6B.

α coefficient represents w_{up/}w_{original}, which is the ratio of the upper width (Wᵤₚ—the width of the plating pattern after plating) of the surface of the wafer to the lower width (W_{original}—the width of the barrier layer pattern before plating) of the surface of the wafer.

The variables related to height in the surface topology are h0, h1, h2, and h3, which represent the heights of different layers or regions. For example, h0 represents the maximum height of the plating pattern when the initial plating process is completed at a predetermined base line, h1 represents the minimum height of the plating pattern formed by the initial plating process, h2 represents the height to the barrier layer 20, and h3 represents the height to the metal line 40 exposed after the barrier layer 20 is removed.

When the measurement of the initial topography is completed, a re-plating process is performed when the height difference (h0−h1) of the surface of the wafer is equal to or less than a predetermined value, i.e., when the difference between the maximum height h0 of the plating pattern formed through a preliminary CMP process after the initial plating process is completed and the minimum height h1 of the plating pattern formed by the initial plating process is equal to or less than the predetermined value, a re-plating process is performed.

That is, if the height difference of the pattern is large, planarization is performed first by the preliminary CMP process, and when the height difference of the pattern is equal to or less than the predetermined value, the re-plating process is performed to minimize the occurrence of dishing and erosion. When the height difference is equal to or less than the predetermined value, which is 10 μm in the embodiment of the present invention, the re-plating process is performed. If the height difference is greater than 10 μm, the plated metal layer may be non-uniform.

In the embodiment of the present invention, the plating process may include at least one of electrolytic plating and electroless plating. That is, only the electrolytic plating may be performed, only the electroless plating may be performed, the electrolytic plating and the electroless plating may be performed, or each of the electrolytic plating and the electroless plating may be repeated a plurality of times depending on the initial topography.

When the metal interconnection layer 30 is removed in the CMP process, a part of the metal interconnection layer 30 may be excessively removed from the surface of the wafer (dishing and erosion), resulting in thickness non-uniformity. In order to solve this problem, a plating process is required, and the metal layer on the surface of the wafer is reconfigured by plating to maintain surface uniformity. In response to this need, the present invention solves the surface non-uniformity by performing the plating process during the CMP process and selectively depositing a metal on the surface of the wafer through the electrolytic plating and electroless plating processes.

In general, electrolytic plating is the deposition of metal ions on the surface of the wafer using current, and has the advantage of uniformly depositing a metal layer (metal interconnection layer) and enabling high-speed plating. In the embodiment of the present invention, low points of the surface may be filled and the metal layer may be uniformly deposited by electrolytic plating when there is a large height difference on the surface of the wafer, and if the metal interconnection layer 30 remains, electrolytic plating is mainly performed thereon.

In addition, electroless plating is a method of depositing a metal on the surface of the wafer through chemical reaction without using current, wherein metal ions are reduced on the surface of the wafer to form a metal layer, whereby plating may be performed even on an electrically non-conductive or complex structure, a uniform plating thickness may be obtained, and a specific region may be selectively plated.

At least one of metal materials having excellent electrical conductivity, such as Cu, Al, Au, Ag, Ni, Cr, Zn, and Sn, may be used as the plating material according to the embodiment of the present invention.

In addition, depending on the shape or structure of the device, the plating process may be selectively applied to a specific region of the surface of the wafer based on the initial topography. That is, in consideration of the non-uniformity of the surface of the wafer, or if dishing and erosion are more likely to occur in the specific region, the plating process may be performed only in the region. In this case, electroless plating may be appropriately used. If electrolytic plating is performed, only the exposed region is plated in the state in which other regions are masked.

In addition, the electroless plating process may be performed in a specific region of the surface of the wafer where the height of the surface of the wafer is equal to or less than the reference value (h3) before and/or after the CMP process.

That is, during the CMP process, the non-uniformity of some regions of the surface of the wafer is not removed or regions that are polished more than expected occur, and in order to solve this problem, electroless plating is used to deposit a metal in a specific region that needs to be plated and then the region is planarized again.

The height h3 of the surface of the wafer before and/or after the CMP process is the height to the metal line 40 exposed after the barrier layer 20 is removed, wherein electroless plating is used to deposit a metal on a lower part of the surface of the wafer and to selectively deposit the metal on a non-uniform part, a complex structure, or a region that is not electrically conductive.

In addition, the electroless plating process may be further performed depending on the non-uniformity of the surface of the wafer. That is, if the surface of the wafer is still non-uniform even after the CMP process, the electroless plating process may be further performed to compensate for the non-uniformity. This method is performed to make the surface of the wafer more uniform by selectively applying electroless plating if complete planarization is not achieved even through the CMP process, the re-plating process, and the CMP process. Electroless plating is used to deposit a metal on a lower part of the surface of the wafer and to selectively deposit the metal on a non-uniform part, a complex structure, or a region that is not electrically conductive.

After the CMP process, the surface is remeasured, and electroless plating is further performed if the non-uniformity of the surface of the wafer is equal to or greater than a reference level. Since this process does not require current, the process may be effectively performed even on a complex structure or a non-conductive area. Subsequently, the CMP process may be performed again to finally planarize the surface. This minimizes the non-uniformity of the surface of the wafer and maximizes the performance of the quantum device.

In addition, according to the embodiment of the present invention, the plating thickness may be automatically adjusted by detecting the non-uniformity of the surface of the wafer during the plating process.

If the plating process is not properly performed in the semiconductor device manufacturing process, non-uniformity remains on the surface of the wafer and interferes with signal transmission and device performance. Therefore, the state of the surface of the wafer may be monitored in real time during plating to ensure that the plating thickness is adjusted precisely to the required region only, thereby preventing unnecessary plating and optimizing the planarization of the surface of the wafer.

Detection of non-uniformity is accomplished by measuring the height difference of the surface of the wafer using the measurement unit (optical sensor or laser scanning equipment) 600 described above, and the controller 700 transmits this data to the plating equipment 300 to cause a change in the plating process conditions.

As one of methods of automatically adjusting the plating thickness, electrolytic plating may be performed during the plating process, wherein a pulse reverse current process may be performed during a pulse forward current process or the pulse forward current process and the pulse reverse current process may be repeated.

Electrolytic plating may quickly deposit metal ions on the surface of the wafer using current, which is advantageous for forming a metal layer with a uniform thickness, and the pulse forward current process is performed to deposit metal ions on the surface of the wafer while keeping the current constant. At this time, the thickness of the plating may be precisely adjusted according to the intensity and duration of the current. If this process is used alone, the uniformity of the plating layer may be reduced due to non-uniform concentration of the metal ions or the local current density difference on the surface of the wafer.

To this end, in the embodiment of the present invention, a current flows in a direction opposite the pulse forward current, thereby temporarily removing a part of the metal from the surface of the wafer, and this process serves to remove defects in the metal layer and to increase the uniformity of the plating layer.

That is, local non-uniformity may occur on the surface of the wafer during plating, and the non-uniform part of the surface may be planarized by temporarily removing the metal using the pulse reverse current.

In the embodiment of the present invention, the pulse forward current process and the pulse reverse current process are alternately performed, wherein the pulse forward current process is advantageous for quickly and uniformly depositing the metal, but when local non-uniformity occurs, the pulse reverse current is provided to remove the non-uniformity while temporarily removing the metal layer. In this case, the metal layer may be more precisely deposited, whereby it is possible to form a high-quality metal layer with reduced surface defects.

That is, if only the pulse forward current process is used for a wafer having a complex pattern, there may be excessive metal deposition in a specific region, and therefore the pulse reverse current process is performed to solve this problem, whereby uniform plating is achieved.

In addition, as the plating process proceeds, the upper width (Wᵤₚ—the width of the plating pattern after plating) of the surface of the wafer may be less than the lower width (W_{original}—the width of the barrier layer pattern before plating) of the surface of the wafer. As the plating process is completed, the topology may be changed, as shown in FIG. 8B.

The α coefficient w_{up/}w_{original}, which is the ratio of the upper width (Wᵤₚ—the width of the plating pattern after plating) of the surface of the wafer to the lower width (W_{original}—the width of the barrier layer pattern before plating) of the surface of the wafer, is 0.99 or less, the re-plating may be stopped and the CMP process may be performed. When the α coefficient is closer to 1, this means that the plating layer maintains the shape of the original pattern well, and when the α coefficient is equal to or less than 0.99, this means that the plating has reached an appropriate level, whereupon the plating process is stopped and the CMP process is performed.

That is, as shown in FIGS. 8A and 8B, plating is performed on the pattern, the widths of the pattern before plating and after plating are compared, and if the α coefficient is 0.99 or less, the re-plating may be stopped and the CMP process may be performed. If the re-plating is not stopped even when the α coefficient is greater than 0.99, the plating layer is likely to be too thick or non-uniformly formed.

As such, the α coefficient is an important factor for controlling the plating process and the CMP process, and when the α coefficient reaches 0.99, this indicates that the plating process has been completed. Based on this value, the plating process is stopped and the CMP process is performed to ensure the efficiency and quality of the overall process.

In addition, if the α coefficient is measured in real time, the plating process may be automatically stopped and switched to the CMP process when the α coefficient becomes 0.99 or less during the plating process. This enables automation of the process and prevents unnecessary plating. In the embodiment of the present invention, this function may be controlled by the controller 700. That is, the end point of the plating process and the start point of the CMP process may be clearly set using the α coefficient, thereby maximizing process efficiency.

When the re-plating process is completed, the CMP process is performed for surface planarization of the surface of the wafer. In the CMP process, which is used in the semiconductor device manufacturing process, chemical reaction and mechanical polishing are simultaneously applied to uniformly planarize the surface of the semiconductor device such that subsequent processes can be stably performed. In particular, the CMP process is performed to remove non-uniformity between layers and to form a flat surface in a semiconductor device having a multilayered structure.

In general, the non-uniformity of the surface of the wafer is removed by fixing the wafer on a polishing pad and polishing the surface with a slurry, and the slurry causes chemical reaction that selectively removes a specific material on the surface of the wafer and at the same time a polishing agent mechanically shaves off the surface of the wafer.

In the embodiment of the present invention, since the slurry is used to remove layers such as an oxide, a metal, and an insulating film, a polishing particle, such as silica (SiO₂) or alumina (Al₂O₃), may be used, or an alkaline slurry may be used to remove an oxide film. An appropriate slurry is selected, and the CMP process is performed. The insulating film on the surface of the wafer is removed to planarize the surface of the wafer, the metal interconnection layer 30 is formed, and the top of the metal interconnection layer is planarized to facilitate subsequent processes, or each layer in a multilayered semiconductor device is planarized to reduce a misalignment error.

After the plating process and the CMP process, the uniformity of the surface of the wafer is remeasured to determine whether an additional plating process and an additional CMP process are required. If additional plating process and the additional CMP process are required, the CMP process and the plating process are repeated one or more times. After each process, the state of the surface is checked, and the process is repeatedly performed as necessary.

The remeasurement of the uniformity of the surface of the wafer is performed by the measurement unit 600 using the optical sensor or the like, similarly to the measurement of the initial topography described above.

That is, after the CMP process is completed, the uniformity of the surface is remeasured once again to determine whether an additional plating process or an additional CMP process is required, if necessary. If required, the additional plating process is performed, the additional CMP process is performed, and finally planarization of the surface is completed. The possibility of dishing and erosion is prevented by the re-plating and additional plating process.

The CMP process and the plating process according to the embodiment of the present invention may be performed in an inert gas atmosphere in order to prevent oxidation of the surface of the wafer. Any one of He, Ar, Ne, Kr, and N₂ or a mixture of two or more thereof may be used as the inert gas.

During the CMP process or the plating process, the surface of the wafer may be oxidized, which may reduce the electrical conductivity of the metal and impair signal transmission during the formation of the metal interconnection layer 30. In particular, for quantum semiconductor devices, this may be detrimental to the performance of the devices.

In the embodiment of the present invention, the inert gas is supplied by the inert gas supply unit 500 during the CMP process and the plating process to prevent the metal layer from oxidizing by blocking contact with oxygen.

In the embodiment of the present invention, the pressure in the CMP equipment 200 and the plating equipment 300 may be set to about 5 to 200 mbar higher than atmospheric pressure. This ensures a high concentration of the inert gas while preventing outside air or contaminants from entering the equipment to prevent oxidation of the surface of the wafer and maintain a clean surface.

According to the embodiment of the present invention, the controller 700 controls the pressure through a pressure sensor and a check valve, monitors the pressure in real time to maintain a state of 5 to 200 mbar higher than atmospheric pressure, and maintains a constant pressure and atmosphere in the equipment in conjunction with the inert gas supply unit 500. That is, the pressure in the CMP equipment 200 and the plating equipment 300 is constantly maintained as the inert gas is continuously supplied thereinto.

In addition, a cleaning process of removing residual impurities on the surface of the wafer after the CMP process may be included. After the CMP process is completed, residual impurities (polishing residues and chemical by-products) may remain on the surface of the wafer, and the residual impurities are removed using ultrapure water or a chemical cleaner and the wafer is dried.

In addition, if no additional plating process and CMP process are required after the plating process and the CMP process, a protective film may be further formed in order to protect the surface of the wafer.

If no additional plating process or CMP process is required, a mechanical polishing process may be further performed to remove unnecessary residues or roughness. According to the embodiment of the present invention, a mechanical polishing method, such as buffing or lapping, is used.

Also, in the embodiment of the present invention, an oxide (SiO₂), a nitride (Si₃N₄), or the like may be used to prevent the plated metal layer from being corroded by oxygen, moisture, or the like in the air in order to protect the surface of the wafer.

FIG. 3 shows a chemical mechanical planarization method in a semiconductor manufacturing process according to an embodiment of the present invention, wherein at least one process of applying an electric field during a CMP process is performed, FIG. 5 shows a process of applying an electric field during a CMP process, followed by an additional plating process, and FIG. 7 shows a process of applying an electric field during a CMP process, followed by an additional plating process, followed by an additional CMP process. Between the respective processes, a cleaning process and a drying process are performed.

FIGS. 4A, 4B, 4C, 4D, and 4E are schematic views showing the processes according to the embodiment of FIG. 3, wherein FIG. 4A shows a wafer (device) in which a barrier layer 20 is formed on a dielectric layer 10 and a metal interconnection layer 30 is formed on the barrier layer by an initial plating process. FIG. 4B shows that a CMP process is performed to polish a part of the metal interconnection layer 30. FIG. 4C shows that the initial topography of the surface of the wafer is measured, the non-uniformity of the surface of the wafer is measured, the height difference of the surface of the wafer is determined to be equal to or less than a reference value, and a re-plating process is performed. FIGS. 4D and 4E show that the re-plating process is stopped according to the α coefficient and a CMP process is performed. After the plating process and the CMP process, the uniformity of the surface of the wafer is remeasured to determine that no additional plating process and CMP process are required, and the CMP process is completed. In the embodiment of FIGS. 4A, 4B, 4C, 4D, and 4E, an electric field may be applied for electrophoresis during each CMP process.

FIG. 5 shows a chemical mechanical planarization method in a semiconductor manufacturing process according to an embodiment of the present invention, wherein an electric field (current) is applied at least once during a CMP process and then an electrolytic plating process is performed. In addition, a CMP process, an electroless plating process, and a CMP process may be further performed again to realize planarization of the surface of the wafer. Between the respective processes, a cleaning process and a drying process are performed.

FIGS. 6A, 6B, 6C, 6D, 6E, 6F, and 6G are schematic views showing the processes according to the embodiment of FIG. 5, wherein FIG. 6A shows a wafer (device) in which a barrier layer 20 is formed on a dielectric layer 10 and a metal interconnection layer 30 is formed on the barrier layer by an initial plating process. FIG. 6B shows that a CMP process is performed to polish a part of the metal interconnection layer 30. FIG. 6C shows that the initial topography of the surface of the wafer is measured, the non-uniformity of the surface of the wafer is measured, the height difference of the surface of the wafer is determined to be equal to or less than a reference value, and a re-plating process is performed. FIG. 6D shows that the re-plating process is stopped according to the α coefficient and a CMP process is performed. After the plating process and the CMP process, the uniformity of the surface of the wafer is remeasured, and an additional plating process and an additional CMP process are required, whereby electroless plating is further performed, as shown in FIG. 6E. Subsequently, as shown in FIG. 6F, a CMP process is performed to achieve surface planarization. Subsequently, the uniformity of the surface of the wafer may be remeasured, and if it is determined that additional plating and CMP processes are required, electroless plating may be further performed. In the embodiment of FIGS. 6A, 6B, 6C, 6D, 6E, 6F, and 6G, an electric field may be applied for electrophoresis during each CMP process.

This may minimize dishing and erosion issues and achieve high level planarization of surface of the wafer planarization through an electric field application process or a plating process during the CMP process.

FIG. 7 shows that an electric field (current) is applied at least once during a CMP process, an additional plating process is performed, and an additional CMP process is performed. Between the respective processes, a cleaning process and a drying process may be performed.

Hereinafter, a chemical mechanical planarization apparatus in a semiconductor manufacturing process according to an embodiment of the present invention will be described. A description of parts identical to those that have been described above will be omitted.

As shown in FIG. 9, a chemical mechanical planarization apparatus in a semiconductor manufacturing process according to an embodiment of the present invention, which is an apparatus for performing chemical mechanical planarization, includes CMP equipment 200 configured to perform a CMP process and an electric field application controller 720 configured to apply an electric field to the surface of a wafer.

According to the embodiment of the present invention, the apparatus for performing chemical mechanical planarization in the semiconductor manufacturing process includes CMP equipment 200 formed on one side of device formation equipment 100, the CMP equipment being configured to perform a CMP process of planarizing the surface of a wafer, plating equipment 300 formed on one side of the CMP equipment 200, the plating equipment being configured to perform a plating process of plating the surface of the wafer, a measurement unit 600 configured to detect non-uniformity by measuring initial topography of the surface of the wafer provided by the device formation equipment 100, a controller 700 configured to control the CMP equipment 200 and the plating equipment 300 by detecting the height difference (h0−h1) of the surface of the wafer measured by the measurement unit 600, and a transfer system configured to transfer the wafer from each of the device formation equipment 100, the CMP equipment 200, and the plating equipment 300.

According to the embodiment of the present invention, the apparatus serves to adjust the distribution of charged particles and to control the etch rate of the surface of the wafer by applying the electric field during the CMP process. The apparatus improves the uniformity of etching and minimizes dishing and erosion by concentrating the electric field on a specific region of the surface of the wafer through the electric field application controller 720. The apparatus provides higher precision in the planarization of the surface of the wafer since the controller 700 including the electric field application controller 720 capable of performing electric field application is added, unlike general CMP equipment.

The wafer manufactured by the device formation equipment 100 is transferred to the CMP equipment 200 and the plating equipment 300 to perform each process. The device formation equipment 100 according to the embodiment of the present invention performs the process in a vacuum, and may be PVD equipment or an e-beam evaporator.

The CMP equipment 200 is formed on one side of the device formation equipment 100, is configured to planarize the surface of the wafer, physically polishes the surface of the wafer using a polishing pad and a slurry, and forms a uniform surface through chemical reaction.

The plating equipment 300 is configured to deposit a metal interconnection layer 30 on the surface of the wafer after the CMP process, and may include at least one of electrolytic plating equipment 300 and electroless plating equipment 300.

The measurement unit 600 is configured to measure the topography of the surface of the wafer, and may be used to measure the height difference on the surface of the wafer in order to determine flatness after the CMP process or to measure the thickness of the metal interconnection layer 30 before and after plating. That is, the measurement unit may be used to measure the initial topography or for remeasurement after the CMP process, whereby it is possible to determine whether an additional CMP process is required.

The controller 700 may control the CMP equipment 200 and the plating equipment 300, and may automatically adjust the process based on the data measured by the measurement unit 600. The controller 700 determines whether to perform the CMP process and the plating process based on the height difference (h0−h1) of the surface of the wafer. That is, the controller 700 performs control such that the plating process is performed when the height difference of the surface of the wafer is equal to or less than a reference value or such that an additional CMP process is performed if necessary. In addition, the controller 700 may automatically control the operation of the CMP equipment 200 and the plating equipment 300 based on the data measured in real time.

The transfer system (e.g., a robotic arm) is configured to smoothly transfer the wafer between the device formation equipment 100, the CMP equipment 200, and the plating equipment 300, and prevents contamination or oxidation that may occur during the process while moving the wafer in a vacuum.

That is, the transfer system safely transfers the wafer in a vacuum, smoothly performs the connection between the device formation process, the CMP process, and the plating process, and prevents oxidation of the surface of the wafer between the processes.

In the chemical mechanical planarization apparatus in the semiconductor manufacturing process according to the embodiment of the present invention, a wafer is provided from the device formation equipment 100 under vacuum, and the CMP equipment 200, the plating equipment 300, the measurement unit 600, the controller 700, and the transfer system are included, wherein the initial topography of the wafer is measured to determine non-uniformity, a CMP process is performed to remove the non-uniformity of the wafer, the surface of the wafer is plated with a metal after the CMP process, the flatness of the surface is measured after plating, the controller 700 determines whether an additional CMP process or an additional plating process is required, and the transfer system safely transfers the wafer between all of these processes without contamination.

Meanwhile, in order to maintain a vacuum in the device formation equipment 100 and to maintain an inert gas atmosphere in the CMP equipment 200 for the CMP process and the plating equipment 300 for the plating process, one or more partitions 400 may be included between the device formation equipment 100, the CMP equipment 200, and the plating equipment 300.

The partitions 400 installed between the device formation equipment 100, the CMP equipment 200, and the plating equipment 300 are designed to maintain the process atmosphere during the transfer of the wafer between the respective processes, and are configured to protect the wafer from vacuum breakage, oxidation, contamination, etc. that may occur as the wafer is transferred between equipment.

According to the embodiment of the present invention, the partition 400 is configured to be open while the wafer is being transferred and closed during each process. For example, the partition 400 is opened by a sensor when the wafer arrives at a transfer zone and closed when the transfer is completed, and may be made of a chemically stable metal or a highly durable synthetic material. For example, the partition may be made of tempered glass or stainless steel. In addition, the function of the partition may be performed by a load lock in vacuum equipment.

According to the embodiment of the present invention, during the CMP process, an electric field is applied to the surface of the wafer by the electric field application controller 720 to induce the movement of charged particles in a slurry and to adjust the local etch rate of a metal surface. The electric field application and standby steps are periodically repeated to prevent excessive etching and to achieve uniform planarization. After the CMP process, the uniformity of the surface of the wafer is evaluated, and if the uniformity is equal to or less than a reference level, plating and an additional CMP process are performed to ensure uniformity. Electrolytic plating and electroless plating are selectively performed to maintain a uniform etch rate of the surface of the wafer. An inert gas is supplied to prevent oxidation of the surface of the wafer during the CMP process or the plating process.

FIGS. 10A, 10B, 10C, and 10D are schematic views showing various embodiments of applying an electric field to a wafer in a chemical mechanical planarization apparatus in a semiconductor manufacturing process according to an embodiment of the present invention, wherein various electric field application methods of planarizing the surface of the wafer using a slurry and an electric field in a semiconductor CMP process are shown.

As shown in FIG. 10A, the apparatus includes a conductive substrate (conductor plate), a wafer (substrate), an insulator, a slurry, a platen (polishing pad), a voltage source (electric field application controller), and a controller. The conductor plate is located above the wafer, and forms an electric field through the wafer and the insulator. An electric field is applied by forming a potential difference between the conductor plate and the platen through the voltage source, and the movement of charged particles in the slurry is induced through the electric field. In this method, the distribution and movement of the charged particles in the slurry may be controlled by applying a perpendicular electric field to the surface of the wafer. This allows the etch rate of the surface of the wafer to be uniformly adjusted and the desired flatness to be achieved. In addition, the effects of impurities such as oxidation may be minimized by supplying an inert gas.

Since an inert gas supply unit is provided, it is possible to prevent oxidation of the wafer during a CMP process using an inert gas (e.g., argon or helium) and to stabilize the behavior of the charged particles in the slurry during electric field application, enabling uniform etching.

As shown in FIG. 10B, the apparatus includes a conductor plate, a wafer (substrate), an insulator, a slurry, a platen, a voltage source (electric field application controller), and a controller, and generates an electric field on the surface of the wafer by applying voltage through the conductor plate. The electric field is designed to uniformly distribute the charged particles in the slurry. The distribution of the charged particles in the slurry is uniformly controlled in order to planarize the surface of the wafer. This enables precise planarization to be achieved by minimizing a small height difference on the surface of the wafer.

As shown in FIG. 10C, the apparatus includes a conductor plate (including a part of an insulator), a wafer (substrate), a slurry, a platen, a voltage source (electric field application controller), and a controller, wherein a part of the conductor plate is made of an insulating material, thereby controlling an electric field to be concentrated only in a specific region. A part of the conductor plate is made of an insulating material to adjust the concentration of the electric field. This allows for finer control of the etch rate of the surface of the wafer and allows for local planarization by concentrating the electric field in the specific region.

As shown in FIG. 10D, the apparatus includes a conductor plate, a wafer (substrate), an insulator, a slurry, a platen, a current source (electric field application controller), and a controller, and adjusts charged particles in the slurry by directly applying a current to the wafer through the conductor plate. Current flows through the current source to form an electric potential and to control the movement of ions in the slurry. Planarization is performed by applying current rather than voltage. This allows for local electric field formation in a specific region and fine adjustment of the etch rate of the surface of the wafer. As a result, more accurate planarization may be performed.

These methods control the distribution of charged particles in the slurry by applying an electric field to the surface of the wafer or allowing current to flow through the wafer, thereby adjusting the etch rate of the surface of the wafer and performing planarization. Each method is applicable depending on the process conditions, and may achieve effects such as uniform planarization of the surface, oxidation prevention, and precise etch rate control.

As described above, the various methods shown in FIGS. 10A to 10D implement planarization of the surface of the wafer by applying the electric field, and adjust the etch rate by controlling the distribution of ions and the movement of charged particles in the slurry during the process. As a result, it is possible to secure high level planarization, anti-oxidation, and uniform process conditions of the wafer during semiconductor manufacturing.

As such, the electric field application controller according to the embodiment of the present invention serves to apply the electric field to the surface of the wafer during the CMP process, thereby adjusting the movement and distribution of charged particles in the slurry to control the etch rate of the surface of the wafer.

As described above, the electric field application controller serves to apply the electric field to the surface of the wafer to form the potential difference between the metal and the insulator, thereby controlling the distribution of charged particles in the slurry. This electric field affects the surface etch rate, which may be adjusted to enable a uniform planarization process.

In addition, the electric field application controller finely adjusts the intensity and direction of the electric field in order to adjust the local etch rate of the surface of the wafer. For example, the electric field application controller may apply a stronger electric field to a specific region to increase or decrease the etch rate in the region, thereby inducing surface planarization.

In addition, the electric field application controller locally controls the etch rate by forming an electric potential at a specific position on the surface of the wafer to change the local distribution of charged particles in the slurry. This allows for uniform etch rates in regions with different metal pattern densities.

In addition, the electric field application controller precisely adjusts the etch rate by periodically repeating the electric field application step and the standby step. This prevents local non-uniformity during the planarization process.

In addition, the electric field application controller finely controls the electric field by adjusting voltage such that no current flows on the surface of the wafer when applying the electric field or by locally applying current through the conductive substrate to form an electric potential. The movement and reaction of ions in the slurry are controlled to optimize the etch rate through the adjustment.

In addition, the electric field application controller may ensure uniformity of the electric field over the entirety of the surface of the wafer and may differently apply the electric field to the region with high metal area density and the region with low metal area density. This function compensates for regional etch non-uniformity and improves the final level of planarization.

As such, the electric field application controller is configured to use the electrophoretic phenomenon during the entire CMP process, and plays an important role in precisely adjusting the intensity, direction, application time, etc. of the electric field to achieve optimal etch rate with uniform surface planarization.

As is apparent from the above description, according to an embodiment of the present invention, it is possible to locally adjust the etch rate of the surface of a wafer by applying an electric field or current to control the distribution of charged particles in a slurry. As a result, it is possible to minimize excessive dishing or erosion in a CMP process and to achieve uniform planarization of the surface.

In addition, it is possible to concentrate charged particles (cations and anions) in the slurry on a specific part of the surface of the wafer by controlling the charged particles using an electric field or current. As a result, it is possible to control the etch rate of a metal and an insulator, allowing for selective planarization of only the desired part.

In addition, it is possible to prevent oxidation of the surface of the wafer by performing a process in an inert gas atmosphere or by introducing an insulator. This prevents oxidization of a metal interconnection layer and degradation of electrical properties thereof, thereby improving process quality.

In addition, it is possible to prevent unnecessary etching and to efficiently remove materials during the CMP process by periodically applying the electric field and adjusting the application cycle. In addition, if the measured uniformity of the surface of the wafer is equal to or less than a reference level, it is possible to improve productivity by reducing the number of repetitions of CMP processes and plating processes.

In addition, it is possible to locally concentrate the electric field on a specific region using a conductor plate including an insulator or a current application method. As a result, it is possible to effectively reduce the height difference of a complex pattern or a specific region.

In addition, it is possible to apply different electric fields to a region with high metal area density and a region with lower metal area density by controlling the symmetry in distribution of the electric field and the intensity of the electric field. As a result, it is possible to control local etch rate while maintaining uniformity of the entirety of the surface of the wafer.

According to the embodiment of the present invention, as described above, the CMP process may be improved to minimize dishing and erosion issues and to improve the flatness of the surface of the wafer, whereby it is possible to manufacture a high-quality quantum device.

In addition, it is possible to solve oxidation and contamination problems that may occur during the successive CMP and plating processes and to improve productivity through an automated transfer system and precise process control between processes.

As a result, it is possible to manufacture a high-quality quantum device, whereby it is possible to provide excellent performance in high-precision applications such as quantum computing and quantum communication.

What is claimed is:

1. A chemical mechanical planarization method in a semiconductor manufacturing process, wherein the chemical mechanical planarization method is performed to apply an electric field to a surface of a wafer using an electrophoretic phenomenon during a chemical mechanical planarization (CMP) process in order to control distribution of charged particles in a slurry.

2. The chemical mechanical planarization method according to claim 1, wherein the electric field is applied perpendicular to the surface of the wafer to change distribution of ions in the slurry according to a potential difference between a metal and an insulator, thereby adjusting a local etch rate of a metal surface.

3. The chemical mechanical planarization method according to claim 2, wherein positively or negatively charged ions in the slurry are concentrated on the metal surface through application of the electric field, thereby reducing the etch rate of the metal.

4. The chemical mechanical planarization method according to claim 2, wherein a plating process is performed after the CMP process, uniformity of the surface of the wafer is measured after the CMP process and the plating process, and if the uniformity is equal to or less than a reference level, additional plating and CMP processes are repeated.

5. The chemical mechanical planarization method according to claim 4, wherein the plating process comprises at least one of an electrolytic plating process and an electroless plating process.

6. The chemical mechanical planarization method according to claim 4, wherein, if a height difference (h0−h1) of the surface of the wafer measured after the plating process and the CMP process is equal to or less than a reference value, the plating process is stopped and the CMP process is performed when α coefficient (Wᵤₚ/W_{original}), which is a ratio of a surface width before plating to the surface width after plating, is 0.99 or less.

7. The chemical mechanical planarization method according to claim 1, wherein voltage is applied such that no current flows on the surface of the wafer to form an electric field, and movement of the charged particles in the slurry through the electric field is adjusted to control an etch rate of the surface of the wafer.

8. The chemical mechanical planarization method according to claim 1, wherein an etch rate of the surface of the wafer is adjusted by applying current to the surface of the wafer through a conductive substrate to form a potential difference, thereby generating an electric field.

9. The chemical mechanical planarization method according to claim 1, wherein negatively charged ions in the slurry are concentrated on a metal surface by the electrophoretic phenomenon to reduce an etch rate of the metal.

10. The chemical mechanical planarization method according to claim 1, wherein the CMP process is performed in an inert gas atmosphere.

11. The chemical mechanical planarization method according to claim 1, comprising:
a standby step of applying no electric field, wherein
the electric field application step and the standby step are periodically repeated.

12. The chemical mechanical planarization method according to claim 1, wherein distribution of the electric field is controlled so as to have symmetrical non-uniformity with respect to a center of the surface of the wafer.

13. The chemical mechanical planarization method according to claim 1, wherein an etch rate is adjusted by applying different electric fields to a region with high metal area density and a region with low metal area density.

14. The chemical mechanical planarization method according to claim 1, wherein an electroless plating process is further performed on a specific region of the surface of the wafer.

15. The chemical mechanical planarization method according to claim 14, wherein mechanical polishing is performed on the surface of the wafer after the electroless plating process.

16. The chemical mechanical planarization method according to claim 1, wherein a quantum superconductor material used in semiconductor devices for quantum technology is any one of Nb, Sn, Al, Zn, Ta, Nb—Ti, Nb₃Sn, V₃Si, V₃Ga, Nb₃Ge, MgB₂, YBCO, BSCCO, iron pnictides, LBCO, iron chalcogenides, TBCCO, Hg-1223, and iron-based superconductors or a mixture of two or more thereof.

17. A chemical mechanical planarization apparatus in a semiconductor manufacturing process, wherein the chemical mechanical planarization apparatus comprises CMP equipment configured to perform a CMP process of planarizing a surface of a wafer and an electric field application controller configured to apply an electric field to the surface of the wafer during the CMP process.

18. The chemical mechanical planarization apparatus according to claim 17, wherein the electric field application controller applies the electric field perpendicular to the surface of the wafer to form a potential difference between a metal and an insulator, thereby controlling distribution of ions in a slurry.

19. The chemical mechanical planarization apparatus according to claim 18, wherein negatively or positively charged ions are concentrated on the surface of the wafer to reduce an etch rate of the metal through application of the electric field.

20. The chemical mechanical planarization apparatus according to claim 17, comprising a measurement unit configured to perform a plating process on the surface of the wafer after the CMP process, to measure uniformity of the surface of the wafer after the CMP process and the plating process, and to perform additional plating and CMP processes if the uniformity is equal to or less than a reference level.

21. The chemical mechanical planarization apparatus according to claim 20, comprising at least one of electrolytic plating equipment and electroless plating equipment configured to perform the plating process.

22. The chemical mechanical planarization apparatus according to claim 17, wherein the electric field application controller applies voltage such that no current flows on the surface of the wafer to form an electric field and adjusts movement of the charged particles in the slurry through the electric field to control an etch rate of the surface of the wafer.

23. The chemical mechanical planarization apparatus according to claim 17, wherein the electric field application controller adjusts an etch rate of the surface of the wafer by applying current to the surface of the wafer through a conductive substrate to form a potential difference, thereby locally generating an electric field.

24. The chemical mechanical planarization apparatus according to claim 17, wherein the electric field application controller performs control such that negatively charged ions in the slurry are concentrated on a metal surface by the electrophoretic phenomenon.

25. The chemical mechanical planarization apparatus according to claim 17, comprising an inert gas supply unit configured to perform a CMP process in an inert gas atmosphere in order to prevent oxidation of the surface of the wafer during the CMP process.

26. The chemical mechanical planarization apparatus according to claim 25, wherein the inert gas comprises at least one of He, Ar, Ne, Kr, and N₂.

27. The chemical mechanical planarization apparatus according to claim 17, wherein the electric field application controller performs control such that distribution of the electric field has symmetrical non-uniformity with respect to a center of the surface of the wafer.

28. The chemical mechanical planarization apparatus according to claim 17, wherein the electric field application controller adjusts an etch rate by applying different electric fields to a region with high metal area density on the surface of the wafer and a region with low metal area density on the surface of the wafer.

29. The chemical mechanical planarization apparatus according to claim 17, wherein the electric field application controller periodically repeats an electric field application step and a standby step of applying no electric field to adjust an etch rate of the surface of the wafer.

30. The chemical mechanical planarization apparatus according to claim 17, wherein the electric field application controller controls an intensity and direction of the electric field so as to change over time, thereby adjusting an etch rate of a specific region of the surface of the wafer.

31. The chemical mechanical planarization apparatus according to claim 17, wherein the electric field application controller adjusts distribution of the electric field and a direction of current in order to locally adjust an etch rate of the surface of the wafer.

32. The chemical mechanical planarization apparatus according to claim 17, wherein a quantum superconductor material used in semiconductor devices for quantum technology is any one of Nb, Sn, Al, Zn, Ta, Nb—Ti, Nb₃Sn, V₃Si, V₃Ga, Nb₃Ge, MgB₂, YBCO, BSCCO, iron pnictides, LBCO, iron chalcogenides, TBCCO, Hg-1223, and iron-based superconductors or a mixture of two or more thereof.
